(19) United States
(12) Patent Application Publication
(10) Pub. No.: US 2021/0005632 A1
(43) Pub. Date: Jan. 7, 2021

(54) DISPLAY SUBSTRATE AND METHOD OF MANUFACTURING THE SAME, DISPLAY DEVICE

(71) Applicant: BOE Technology Group Co., Ltd., Beijing (CN)

(72) Inventors: Hsuanwei MAI, Beijing (CN); Hua HUANG, Beijing (CN); Shulei LI, Beijing (CN); Song FANG, Beijing (CN)

(21) Appl. No.: 16/913,435

(22) Filed: Jun. 26, 2020

(30) Foreign Application Priority Data
Jul. 3, 2019 (CN) 201910595839.7

(51) Int. Cl. H01L 27/12; H01L 25/16; H01L 23/00

(52) U.S. Cl. CPC H01L 27/124; H01L 25/167; H01L 27/1248; H01L 2224/0603; H01L 24/03; H01L 24/06; H01L 2224/03462; H01L 27/1259

(57) ABSTRACT

The present disclosure provides a display substrate and a method of manufacturing the same, and a display device. The display substrate includes a base substrate; a driving circuit layer disposed on the base substrate; and a planarization layer disposed on a side of the driving circuit layer away from the base substrate and having a plurality of conductive pads therein, the plurality of conductive pads are respectively electrically coupled to electrodes in the driving circuit layer, and a surface of each of the plurality of conductive pads away from the base substrate is flush with a surface of the planarization layer away from the base substrate.

### CROSS-REFERENCE TO RELATED APPLICATION

This application claims priority to Chinese Patent Application No. 201910595839.7, filed on Jul. 3, 2019, the contents of which are incorporated herein by reference in the entirety.

### TECHNICAL FIELD

The present disclosure relates to the field of display technology, and more particularly, to a display substrate and a manufacturing method thereof, and a display device.

### BACKGROUND

A micro light emitting diode (Micro LED) or a mini light emitting diode (Mini LED) can be transferred from a growth substrate to a display substrate provided with a driving circuit through a transfer process. Generally, the number of Micro LEDs/Mini LEDs transferred in a single transfer process is very large, which has a very high requirement on the flatness of an upper surface of the display substrate.

### SUMMARY

In one aspect, the present disclosure provides a display substrate including: a base substrate; a driving circuit layer located on the base substrate; and a planarization layer located on a side of the driving circuit layer away from the base substrate, the planarization layer has a plurality of conductive pads therein, and a surface of each of the plurality of conductive pads away from the base substrate is flush with a surface of the planarization layer away from the base substrate, and the plurality of conductive pads are electrically coupled to electrodes in the driving circuit layer respectively.

According to an embodiment of the present disclosure, a material of the planarization layer is photoresist.

According to an embodiment of the present disclosure, a height tolerance d1 of the surface of the planarization layer away from the base substrate is in a range from −1 μm to 1 μm.

According to an embodiment of the present disclosure, a height tolerance of a surface of the driving circuit layer away from the base substrate is d2, and a thickness D of the planarization layer in a direction perpendicular to a surface of the base substrate satisfies: |2.5*d2|≤D≤|4*d2|.

According to an embodiment of the present disclosure, the display substrate further includes micro light emitting diodes located on and electrically coupled to the plurality of conductive pads.

According to an embodiment of the present disclosure, a material of each of the plurality of conductive pads includes at least one of Cu, Al, Ag, Au, and In.

In another aspect, the present disclosure provides a method of manufacturing a display substrate, including: forming a driving circuit layer on a base substrate, the driving circuit layer is formed to expose at least part of electrodes in the driving circuit layer; forming a planarization layer on a side of the driving circuit layer away from the base substrate; patterning the planarization layer to form via holes through which the at least part of the electrodes in the driving circuit layer are exposed; and forming conductive pads in the via holes, the conductive pads are formed such that surfaces of the conductive pads away from the base substrate are flush with a surface of the planarization layer away from the base substrate.

According to an embodiment of the present disclosure, the planarization layer is formed of photoresist.

According to an embodiment of the present disclosure, forming a planarization layer on a side of the driving circuit layer away from the base substrate includes: forming a photoresist layer on the side of the driving circuit layer away from the base substrate; and planarizing the photoresist layer.

According to an embodiment of the present disclosure, forming conductive pads in the via holes includes: growing the conductive pads in the via holes through an electroplating process, a current and/or a time parameter of the electroplating process is controlled such that the surfaces of the conductive pads away from the base substrate are flush with the surface of the planarization layer away from the base substrate.

According to an embodiment of the present disclosure, forming conductive pads in the via holes includes: filling a conductive material into the via holes to form the conductive pads, the surfaces of the conductive pads away from the base substrate exceed the surface of the planarization layer away from the base substrate; and planarizing the conductive pads such that the surfaces of the conductive pads away from the base substrate are flush with the surface of the planarization layer away from the base substrate.

According to an embodiment of the present disclosure, the method further includes: transferring micro light emitting diodes to the conductive pads after forming the conductive pads in the via holes.

In another aspect, the present disclosure also provides a display device including the display substrate described herein or manufactured according to the method described herein.

### BRIEF DESCRIPTION OF THE FIGURES

FIG. 1 is a schematic structural diagram illustrating a display substrate according to an embodiment of the present disclosure;

FIG. 2 is a schematic structural diagram illustrating another display substrate according to an embodiment of the present disclosure;

FIG. 3 is a flowchart illustrating a method of manufacturing a display substrate according to an embodiment of the present disclosure;

FIG. 4 is a flowchart illustrating a method of manufacturing a display substrate according to an embodiment of the present disclosure;

FIGS. 5a to 5c are schematic structural diagrams of a display substrate at different manufacturing stages according to an embodiment of the present disclosure.

### DETAILED DESCRIPTION

To make those skilled in the art better understand the technical solutions of the present disclosure, the present disclosure will be further described in detail below in conjunction with the accompanying drawings and embodiments. It should be noted that the following description of some embodiments has been presented for purposes of illustration and description. These embodiments are not intended to be exhaustive or to be limited to the precise forms disclosed, and the repeated description is omitted in order to avoid redundancy.

In order to keep the following descriptions of the embodiments of the present disclosure clear and concise, detailed descriptions of known functions and components may be omitted. When any component of an embodiment of the present disclosure appears in more than one drawings, the component is denoted by a same reference numeral in each drawing.

The present disclosure provides a display substrate and a manufacturing method thereof, and a display device that substantially obviate one or more of the problems due to limitations and disadvantages of the related art. In the present disclosure, by making a surface of a planarization layer (e.g., a photoresist layer) away from a base substrate and a surface of a conductive pad away from the base substrate at a same level, on one hand, the flatness and coplanarity of the display substrate are improved, on the other hand, gaps between a growth substrate and the display substrate can be reduced, thereby improving a mass transfer yield.

An embodiment of the present disclosure provides a display substrate. In some implementations, the display substrate includes: a base substrate; a driving circuit layer disposed on the base substrate; and a planarization layer disposed on a side of the driving circuit layer away from the base substrate, the planarization layer has a plurality of conductive pads therein, surfaces of the plurality of conductive pads away from the base substrate are flush with a surface of the planarization layer away from the base substrate, and the plurality of conductive pads are electrically coupled to electrodes in the driving circuit layer in one-to-one correspondence.

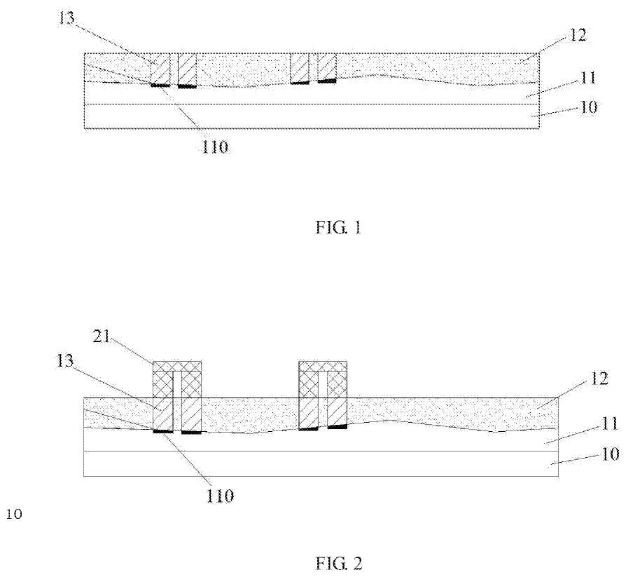

FIG. 1 is a schematic structural diagram illustrating a display substrate according to an embodiment of the present disclosure. Referring to FIG. 1, in some implementations, the display substrate may include: a base substrate 10, a driving circuit layer 11 disposed on the base substrate 10, and a planarization layer 12 disposed on a side of the driving circuit layer 11 away from the base substrate 10 and having a plurality of conductive pads 13 therein, the plurality of conductive pads 13 are electrically coupled to the respective electrodes 110 in the drive circuit layer 11, respectively, and surfaces of the plurality of conductive pads 13 away from the base substrate 10 are flush (i.e., coplanar or at a same level) with the surface of the planarization layer 12 away from the base substrate 10.

In some implementations, a material of the base substrate 10 may be, for example, glass. The driving circuit layer 11 may be provided with signal lines such as a gate line (not shown) and a data line (not shown), and a driving transistor (not shown), etc., for supplying a driving voltage to the conductive pad 13. In some implementations, an upper surface of the driving circuit layer 11 may further include an insulating material. Structures in the driving circuit layer 11 may be similar to those in existing liquid crystal display substrates and OLED display substrates, and repeated description thereof is omitted here.

In some implementations, the electrode 110 may be one electrode of the driving transistor. Alternatively, a part of a certain signal line may be used as the electrode 110. The conductive pad 13 is configured to electrically couple a cathode or anode of a micro LED 21 (shown in FIG. 2) with a respective electrode 110. In addition, the conductive pad 13 may also be configured to fix the micro LED 21. The material of the conductive pad 13 may be, for example, Cu, Al, Ag, Au, In, or the like.

In some implementations, the planarization layer 12 may be formed of photoresist, and thus the planarization layer 12 may be referred to as a photoresist layer. In this embodiment, since a flatness of a surface of the photoresist layer 12 away from the base substrate 10 can be controlled to be higher than a flatness of the surface of the driving circuit layer 11 away from the base substrate 10, and it can realize that the conductive pad 13 and the photoresist layer 12 are coplanar by means of existing manufacturing processes of the conductive pad 13, therefore, when the micro LED 21 is transferred, the flatness of the upper surface of the display substrate is greatly improved, thereby improving a yield of transferring the micro LED 21.

In some implementations, a height tolerance d1 (not shown in the figures) of the surface of the planarization layer (e.g., the photoresist layer) 12 away from the base substrate 10 may be in a range from −1 μm to 1 μm. It should be understood that the smaller the height tolerance d1 of the surface of the planarization layer/photoresist layer 12 away from the base substrate 10, the higher the flatness of the upper surface of the display substrate. In actual practices, the above height tolerance range is enough for most transfer devices.

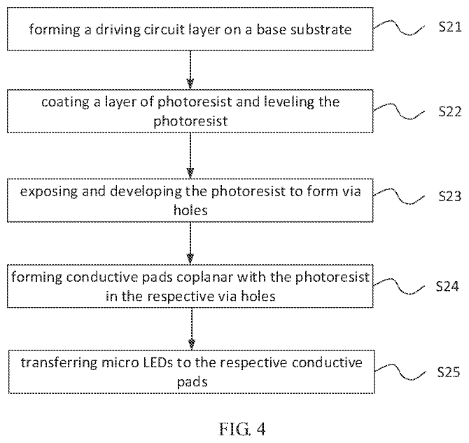

In some implementations, referring to FIG. 4b, a height tolerance of the surface of the driving circuit layer 11 away from the base substrate 10 is d2, and a thickness D of the photoresist layer 12 needs to satisfy: |2.5*d2|≤D≤|4*d2|. If the photoresist layer 12 is too thin, a filling effect on the driving circuit layer 11 having an uneven surface is not significant. If the photoresist layer 12 is too thick, the material cost of the photoresist layer 12 and the subsequent formed conductive pads 13 will be increased and the process time will also be increased. According to practice, the thickness of the photoresist layer 12 in above-mentioned range is a relatively suitable.

In some implementations, as shown in FIG. 2, the display substrate may further include a micro LED 21 fixed on the conductive pad 13. For ease of explanation, FIG. 2 only shows two micro LEDs 21 which are horizontally arranged, but the present disclosure is not limited thereto, and a certain number of the micro LEDs 21 may be provided as needed.

An embodiment of the present disclosure also provides a method of manufacturing a display substrate. In some implementations, the method may include: forming a driving circuit layer on a base substrate, where the driving circuit layer is formed to expose at least some (or at least a part) of the electrodes in the driving circuit layer, forming a planarization layer on a side of the driving circuit layer away from the base substrate; patterning the planarization layer to form via holes through which the exposed at least some of the electrodes in the driving circuit layer are exposed, and forming conductive pads in the via holes respectively, where the conductive pads are formed such that surfaces of the conductive pads away from the base substrate are flush with a surface of the planarization layer away from the base substrate.

In some implementations, the method may further include: forming a photoresist layer on a side of the driving circuit layer away from the base substrate; and planarizing the photoresist layer by using any one of a stewing process, an ultrasonic vibration process, a heating process, etc.

In some implementations, the method may further include: transferring micro LEDs to the conductive pads after forming the conductive pads in the via holes.

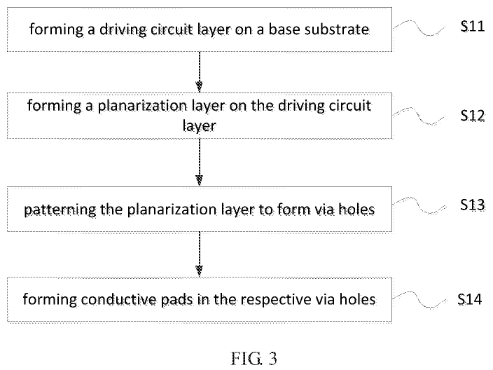

FIG. 3 is a flowchart illustrating a method of manufacturing a display substrate according to an embodiment of the present disclosure. Referring to FIG. 3, the method may include steps S11 to S14.

In step S11, forming a driving circuit layer 11 on a base substrate 10, where the driving circuit layer 11 is formed to expose at least some of the electrodes 110 in the driving circuit layer 11.

In step S12, forming a planarization layer 12 on a side of the drive circuit layer 11 away from the base substrate 10. In some implementations, the planarization layer 12 may be formed of photoresist, but the present disclosure is not limited thereto.

In step S13, patterning the planarization layer 12 formed in step S12 by using a patterning process, to form via holes exposing the exposed electrodes 110 formed in step S11.

In step S14, forming conductive pads 13 in the via holes by using an electroplating or electroforming process, etc., where the conductive pads 13 are formed such that surfaces of the conductive pads 13 away from the base substrate 10 are substantially flush (i.e., coplanar or at a same level) with the upper surface of the photoresist layer 12 away from the base substrate 10, and the conductive pads 13 are respectively electrically coupled to the electrodes 110 respectively.

Since the flatness of the conductive pads 13 and the photoresist layer 12 is greatly improved, gaps between the growth substrate and the display substrate can be reduced, thereby improving the mass transfer yield.

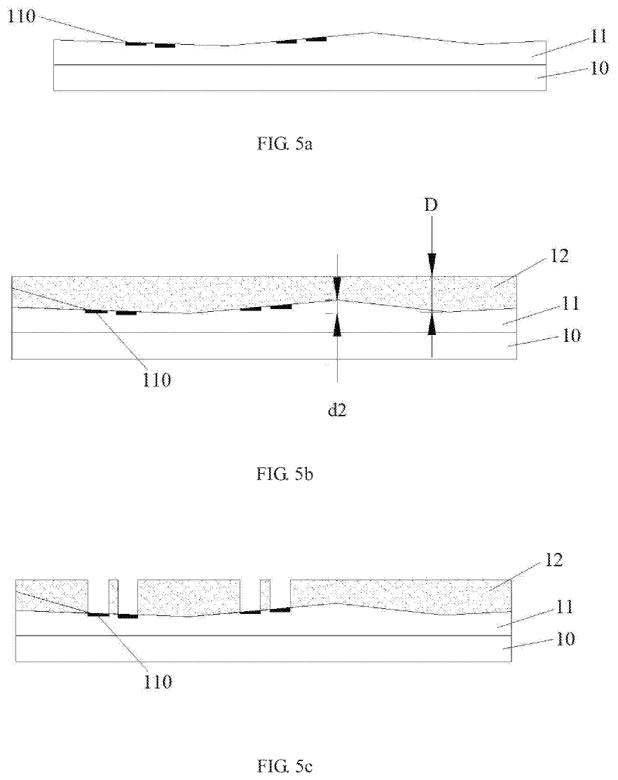

FIG. 4 is a flowchart illustrating a method of manufacturing a display substrate according to an embodiment of the present disclosure. FIGS. 5a to 5c are schematic structural diagrams of a display substrate at different manufacturing stages according to an embodiment of the present disclosure. Referring to FIG. 4 in conjunction with FIGS. 5a to 5c, the method includes steps S21 to S25.

In step S21, forming a driving circuit layer 11 on a base substrate 10, where the driving circuit layer 11 is formed to expose at least some of electrodes 110 in the driving circuit layer 11. A product form after step S21 is completed is shown in FIG. 5a.

In step S22, coating a layer of photoresist on a side of the driving circuit layer 11 away from the base substrate 10, and planarizing (e.g., leveling) the photoresist to form a planarization layer (i.e., a photoresist layer) 12.

In some implementations, the layer of photoresist may be coated on the driving circuit layer 11 by using a process such as slit die coating, dispensing, spraying, spin coating, screen printing or the like.

In some implementations, the photoresist may be subjected to a processes such as stewing, ultrasonic vibration, heating or the like, so as to planarize (e.g., level) the photoresist.

In step S23, exposing and developing the photoresist layer 12 to form via holes that expose the electrodes 110 exposed in step S1. A product form after step S23 is completed is shown in FIG. 5b.

In step S24, forming conductive pads 13 in the via holes respectively, where the conductive pads 13 are formed such that surfaces of the conductive pads 13 away from the base substrate 10 are substantially flush (i.e., coplanar or at a same level) with an upper surface of the photoresist layer 12 away from the base substrate.

In some implementations, a method for controlling the surfaces of the conductive pads 13 away from the base substrate 10 to be substantially flush with the surface of the photoresist layer 12 away from the base substrate 10 is that: the conductive pads 13 are grown in the via holes by using an electroplating process or an electroforming process, where a current and/or a time parameter of the electroplating or electroforming process can be controlled such that the surfaces of the conductive pads 13 away from the base substrate 10 are substantially flush (i.e., coplanar or at a same level) with the surface of the photoresist layer 12 away from the base substrate 10.

In some implementations, the method for controlling the surfaces of the conductive pads 13 away from the base substrate 10 to be substantially flush with the surface of the photoresist layer 12 away from the base substrate 10 is that: a conductive material is filled into the via holes to form the conductive pads 13, where the surfaces of the conductive pads 13 away from the base substrate 10 exceeds the surface of the planarization layer 12 away from the base substrate 10; the conductive pads 13 is then planarized such that the surfaces of the conductive pads 13 away from the base substrate 10 are substantially flush (i.e., coplanar or at a same level) with the surface of the photoresist layer 12 away from the base substrate 10. In some implementations, in order to reduce a workload of planarizing the conductive pads 13, the conductive pads 13 may be grown by using an electroplating or electroforming process.

In step S25, after the conductive pads 13 coplanar with the photoresist layer 12 are formed in the via holes respectively, micro LEDs 21 may be transferred to the conductive pads 13 such that the micro LEDs 21 are electrically coupled to the conductive pads 13 respectively. A product form after step S25 is completed is shown in FIG. 2.

When the micro LEDs 21 on a growth substrate (not shown) are transferred to the display substrate, since the flatness of the conductive pads 13 and the photoresist layer 12 is greatly improved, gaps between the growth substrate and the display substrate can be reduced, thereby increasing the mass transfer yield.

An embodiment of the present disclosure provides a display device including the display substrate described herein or manufactured by the method described herein. In some implementations, the display device includes a display panel. In some implementations, the display panel includes a display substrate described herein or manufactured by the method described herein, and an opposite substrate. Appropriate display devices include, but are not limited to, any products or components with a display function, such as micro-LED or Mini-LED display panels, micro LED display modules, mobile phones, tablet computers, televisions, monitors, notebook computers, digital photo frames, navigators, etc.

It is to be understood that the above description is only for the purpose of illustrating the principles of the present disclosure, but the present disclosure is not limited thereto. Various modifications and improvements can be made by those skilled in the art without departing from the spirit and scope of the disclosure, and such modifications and improvements are also considered to be within the scope of the disclosure.

What is claimed is:

1. A display substrate, comprising:
a base substrate;
a driving circuit layer located on the base substrate; and
a planarization layer located on a side of the driving circuit layer away from the base substrate,
wherein the planarization layer has a plurality of conductive pads therein, and a surface of each of the plurality of conductive pads away from the base substrate is flush with a surface of the planarization layer away from the base substrate, and
wherein the plurality of conductive pads are electrically coupled to electrodes in the driving circuit layer respectively.

2. The display substrate of claim 1, wherein a material of the planarization layer is photoresist.

3. The display substrate of claim 2, wherein a height tolerance d1 of the surface of the planarization layer away from the base substrate is in a range from −1 μm to 1 μm.

4. The display substrate of claim 1, wherein a height tolerance of a surface of the driving circuit layer away from the base substrate is d2, and a thickness D of the planarization layer in a direction perpendicular to a surface of the base substrate satisfies: |2.5*d2|≤D≤|4*d2|.

5. The display substrate of claim 3, wherein a height tolerance of a surface of the driving circuit layer away from the base substrate is d2, and a thickness D of the planarization layer in a direction perpendicular to a surface of the base substrate satisfies: |2.5*d2|≤D≤|4*d2|.

6. The display substrate of claim 5, further comprising:
micro light emitting diodes located on and electrically coupled to the plurality of conductive pads.

7. The display substrate of claim 6, wherein a material of each of the plurality of conductive pads includes at least one of Cu, Al, Ag, Au, and n.

8. A method of manufacturing a display substrate, comprising:
forming a driving circuit layer on a base substrate, wherein the driving circuit layer is formed to expose at least part of electrodes in the driving circuit layer;
forming a planarization layer on a side of the driving circuit layer away from the base substrate;
patterning the planarization layer to form via holes through which the at least part of the electrodes in the driving circuit layer are exposed; and
forming conductive pads in the via holes, wherein the conductive pads are formed such that surfaces of the conductive pads away from the base substrate are flush with a surface of the planarization layer away from the base substrate.

9. The method of claim 8, wherein the planarization layer is formed of photoresist.

10. The method of claim 9, wherein forming a planarization layer on a side of the driving circuit layer away from the base substrate comprises:
forming a photoresist layer on the side of the driving circuit layer away from the base substrate; and
planarizing the photoresist layer.

11. The method of claim 10, wherein forming conductive pads in the via holes comprises:
growing the conductive pads in the via holes through an electroplating process,
wherein a current and/or a time parameter of the electroplating process is controlled such that the surfaces of the conductive pads away from the base substrate are flush with the surface of the planarization layer away from the base substrate.

12. The method of claim 10, wherein forming conductive pads in the via holes comprises:
filling a conductive material into the via holes to form the conductive pads, wherein the surfaces of the conductive pads away from the base substrate exceed the surface of the planarization layer away from the base substrate; and
planarizing the conductive pads such that the surfaces of the conductive pads away from the base substrate are flush with the surface of the planarization layer away from the base substrate.

13. The method of claim 11, further comprising:
transferring micro light emitting diodes to the conductive pads after forming the conductive pads in the via holes.

14. The method of claim 12, further comprising:
transferring micro light emitting diodes to the conductive pads after forming the conductive pads in the via holes.

15. A display device, comprising the display substrate of claim 1.
